(19) United States
(12) Patent Application Publication
(10) Pub. No.: US 2026/0088256 A1
(43) Pub. Date: Mar. 26, 2026

(54) FLOW ADAPTORS FOR GAS FLOWS, AND RELATED PROCESSING CHAMBERS, PROCESSING SYSTEMS, APPARATUS, AND METHODS

(71) Applicant: Applied Materials, Inc., Santa Clara, CA (US)

(72) Inventors: Liurui LI, Santa Clara, CA (US); Borui XIA, Santa Clara, CA (US); Yong ZHENG, San Jose, CA (US)

(21) Appl. No.: 18/895,100

(22) Filed: Sep. 24, 2024

(51) Int. Cl. H01J 37/32; C23C 16/455

(52) U.S. Cl. CPC H01J 37/32449; C23C 16/45591; H01J 37/32633; C23C 16/45506; H01J 2237/3341; H01J 2237/3346

(57) ABSTRACT

Embodiments of the present disclosure generally relate to semiconductor processing equipment. In one or more embodiments, a flow adapter for mounting to a processing chamber includes a first flange, a second flange, and a conduit extending at least partially between the first flange and the second flange. The conduit includes an outer face, an inner flow opening, and one or more angled flow openings extending between the outer face and the inner flow opening. The one or more angled flow openings are oriented at an oblique angle relative to the inner flow opening.

### BACKGROUND

### Field

Embodiments of the present disclosure generally relate to semiconductor processing equipment. More particularly, embodiments of the present disclosure relate to a chemical vapor deposition (CVD) chamber and pedestal for semiconductor fabrication and in situ dry cleaning methods using the same.

### Description of the Related Art

In the fabrication of electronic devices on semiconductor substrates, a substrate can be positioned on a heated pedestal configured to control the temperature of the substrate. Gases can flow over the substrate to process the substrate, such as to deposit on the substrate, pre-clean the substrate, and/or etch the substrate. However, the gas flows can involve turbulence and/or non-uniformity distributions of flow, which can hinder processing.

There is a need, therefore, for gas flow arrangements that facilitate uniform distribution and reduced turbulence.

### SUMMARY

Embodiments of the present disclosure generally relate to semiconductor processing equipment.

In one or more embodiments, a flow adapter for mounting to a processing chamber includes a first flange, a second flange, and a conduit extending at least partially between the first flange and the second flange. The conduit includes an outer face, an inner flow opening, and one or more angled flow openings extending between the outer face and the inner flow opening. The one or more angled flow openings are oriented at an oblique angle relative to the inner flow opening.

In one or more embodiments, a processing system includes a processing chamber that includes a processing volume, a plate assembly operable to supply a gas to the processing volume, and a plasma source assembly operable to supply a plasma gas to the processing volume. The processing system includes a flow adapter coupled between the plate assembly and the plasma source assembly. The flow adapter includes a first flange coupled to the plasma source assembly, a second flange coupled to the plate assembly, an inner flow opening, and one or more angled flow openings extending to the inner flow opening. The one or more angled flow openings are oriented at an oblique angle relative to the inner flow opening.

In one or more embodiments, a method of substrate processing includes generating a plasma, flowing a first gas through a baffle of a conduit and into a processing volume, and flowing a second gas through the baffle of the conduit and into the processing volume. The flowing of the second gas flows at an oblique angle relative to the first gas.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a partial schematic cross sectional side view of a processing system, according to one or more embodiments.

FIG. 2 is a schematic side cross-sectional view of a flow assembly, according to one or more embodiments.

FIG. 3 is an enlarged side cross sectional view of the flow adapter shown in FIG. 2, along Section 3-3 shown in FIG. 5, according to one or more embodiments.

FIG. 4 is a side cross sectional view of the flow adapter shown in FIG. 2, along Section 4-4 shown in FIG. 5, according to one or more embodiments.

FIG. 5 is a schematic top view of the flow adapter shown in FIG. 2, according to one or more embodiments.

FIG. 6 is an enlarged side cross sectional view of a flow adapter, according to one or more embodiments.

FIG. 7 is a schematic top cross sectional view of the baffle shown in FIG. 3, according to one or more embodiments.

FIG. 8 is a schematic block diagram view of a method of substrate processing, according to one or more embodiments.

FIG. 9 is a schematic block diagram view of a method of substrate processing, according to one or more embodiments.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

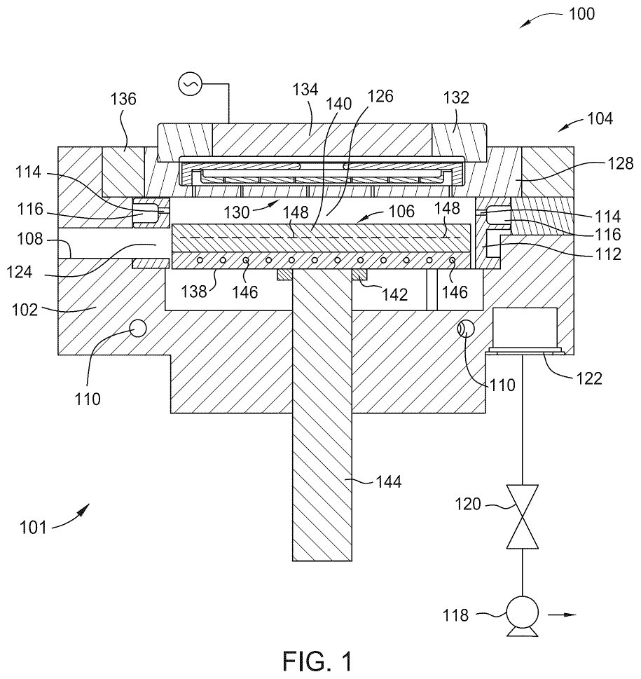

FIG. 1 is a partial schematic cross sectional side view of a processing system 101, according to one or more embodiments. The processing system 101 includes a processing chamber 100, and the processing chamber 100 includes a chamber body 102, a lid assembly 104, and a substrate support 106. In one or more embodiments, the substrate support 106 includes a pedestal. The lid assembly 104 is disposed at an upper end of the chamber body 102, and the substrate support 106 is at least partially disposed within the chamber body 102. The lid assembly 104 can be referred to as a lid assembly. The processing chamber 100 and the associated hardware can be formed from one or more process-compatible materials, such as aluminum.

The chamber body 102 includes a slit valve opening 108 formed in a sidewall thereof to provide access to the interior of the processing chamber 100. The slit valve opening 108 is selectively opened and closed to allow access to the interior of the chamber body 102 by a handling robot. A substrate can be transported in and out of the processing chamber 100 through the slit valve opening 108 to an adjacent transfer chamber and/or load-lock chamber, or another chamber within a cluster tool.

In one or more embodiments, the chamber body 102 includes a channel 110 formed therein for flowing a heat transfer fluid therethrough. The heat transfer fluid can be a heating fluid or a coolant and is used to control the temperature of the chamber body 102 during processing and substrate transfer. The temperature of the chamber body 102 can be controlled to prevent unwanted condensation of the gas or byproducts on the chamber walls. Exemplary heat transfer fluids include water, nitrogen gas, ethylene glycol, or a mixture thereof. Other heat transfer fluids are contemplated.

The chamber body 102 also includes a liner 112 that surrounds the substrate support 106. The liner 112 can be removable for servicing and cleaning. The liner 112 can be made of a metal such as aluminum or stainless steel, silicon carbide (SiC), or a ceramic material. The liner 112 can be any process compatible material. The liner 112 can be bead blasted to increase the adhesion of any material deposited thereon, thereby preventing flaking of material which results in contamination of the processing chamber 100. In one or more embodiments, the liner 112 includes one or more apertures 114 and a pumping channel 116 formed therein that is in fluid communication with a vacuum system. The apertures 114 can provide a flow path for gases into the pumping channel 116, which provides an egress for the gases within the processing chamber 100.

The vacuum system can include a vacuum pump 118 and a throttle valve 120 to regulate flow of gases through the processing chamber 100. The vacuum pump 118 is coupled to a vacuum port 122 disposed on the chamber body 102 and therefore, in fluid communication with the pumping channel 116 formed in the liner 112. An aperture 124 is aligned with the slit valve opening 108 disposed on a side wall of the chamber body 102. The aperture 124 is formed within the liner 112 to allow entry and egress of substrates to/from the chamber body 102. The terms “gas” and “gases” are used interchangeably, unless otherwise noted, and can refer to one or more precursors, reactants, catalysts, carrier, purge, cleaning, etching, combinations thereof, as well as any other fluid introduced into the chamber body 102.

The apertures 114 can allow the pumping channel 116 to be in fluid communication with a processing volume 126 within the chamber body 102. The processing volume 126 can be defined by a lower surface of the lid assembly 104 and an upper surface of the substrate support 106, and can be surrounded by the liner 112. The apertures 114 may be uniformly sized and evenly spaced about the liner 112. Any number, position, size or shape of apertures may be used, and the number, position, size or shape of apertures can vary depending on the flow pattern of gas across the substrate receiving surface as is discussed in more detail below. In addition, the size, number and position of the apertures 114 can be configured to achieve uniform flow of gases exiting the processing chamber 100. The aperture size and location may be configured to provide rapid or high capacity pumping to facilitate a rapid exhaust of gas from the processing chamber 100. For example, the number and size of apertures 114 in closer proximity to the vacuum port 122 may be smaller than the size of apertures 114 positioned farther away from the vacuum port 122.

In operation, one or more gases exiting the processing chamber 100 flow through the apertures 114 formed through the liner 112, and flow into the pumping channel 116. The gas then flows within the pumping channel 116 and through ports into a vacuum channel and exits the vacuum channel through the vacuum port 122 into the vacuum pump 118.

The lid assembly 104 includes a number of components stacked on top of one another, as shown in FIG. 1. In one or more embodiments, the lid assembly 104 includes a lid rim 128, a gas delivery assembly 130, and a top plate 132. The gas delivery assembly 130 is coupled to the lid rim 128 (such as an upper surface of the lid rim 128) and can be arranged to reduce thermal contact with the lid rim 128. The components of the lid assembly 104 can be constructed of a material having a high thermal conductivity and low thermal resistance, such as an aluminum alloy with a highly finished surface for example. The thermal resistance of the components of the lid assembly 104 can be less than about 5×10⁻⁴ m² K/W. The lid rim 128 can hold the weight of the components making up the lid assembly 104 and can be coupled to an upper surface of the chamber body 102 via a hinge assembly to provide access to the internal chamber components, such as the substrate support 106 for example.

The lid assembly 104 includes an electrode 134 to generate a plasma of reactive species within the processing volume 126. In one or more embodiments, the electrode 134 is supported on the top plate 132 and is electrically isolated from the top plate 132. For example, an isolator ring 136 can be disposed about a lower portion of the electrode 134 to separate the electrode 134 from the top plate 132. The isolator ring 136 can be made from aluminum oxide or any other insulative and process compatible material.

In one or more embodiments, the electrode 134 is coupled to a power source and the gas delivery assembly 130 is connected to ground (e.g. the gas delivery assembly 130 can serve as an electrode). Accordingly, a plasma of one or more process gases can be generated in the processing volume 126 and/or within the gas delivery assembly 130.

Any power source capable of activating the gases into reactive species and maintaining the plasma of reactive species may be used. For example, radio frequency (RF), direct current (DC), and/or microwave (MW) based power discharge techniques may be used. The activation may also be generated by a thermally based technique, a gas breakdown technique, a high intensity light source (e.g., UV energy), and/or exposure to an x-ray source. A remote activation source may be used, such as a remote plasma generator, to generate a plasma of reactive species which are then delivered into the processing chamber 100. While the processing chamber 100 is shown and described as a plasma processing chamber, the substrate support 106 as described herein may be utilized in other chambers that are not utilized for plasma processing, such as chemical vapor deposition (CVD) processes.

The substrate support 106 includes a cooling base 138. The cooling base 138 is coupled to a support member 140 and a flange 142 of a stem 144. The cooling base 138 includes a plurality of cooling channels 146 formed therein for flowing a coolant. The support member 140 includes a plurality of heating elements 148. The heating elements 148 can function as a multi-zone heater.

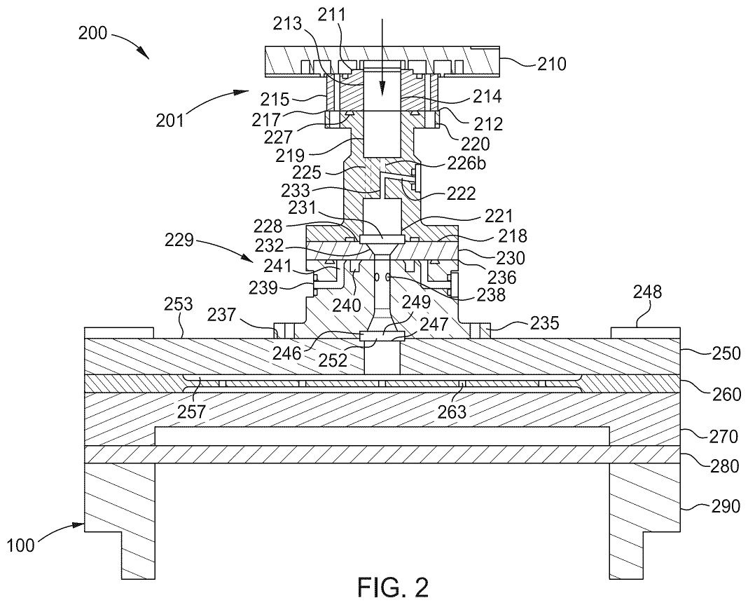

FIG. 2 is a schematic side cross-sectional view of a flow assembly 200, according to one or more embodiments. The flow assembly 200 includes a plasma source 210. At least part of the flow assembly 200 can be used in place of at least part of the lid assembly 104 in FIG. 1. The flow assembly 200 can be coupled to the processing chamber 100 in FIG. 1. The plasma source 210 may be coupled with one or more of an isolator 215, an flow adapter 220, a spacer 230, and a mixing manifold 235. The mixing manifold 235 may be coupled with a top of processing chamber 205, and may be coupled with an inlet to processing chamber 205.

The isolator 215 may be coupled with plasma source 210 at a first end 211, and may be coupled with the flow adapter 220 at a second end 212 opposite the first end 211. Through isolator 215 may be defined one or more flow openings 213, 214. A central flow opening 213 extending through the first end 211 may be used. The central flow opening 213 may transition to smaller flow openings 214 extending from a base of the central flow opening 213 defined within the isolator 215 through second end 212. As an example, one such smaller flow opening 214 is illustrated in FIG. 2 although it is contemplated that any number of smaller flow openings 214 may be used. The isolator 215 may also define one or more trenches defined beneath isolator 215. The trenches may be or include one or more annular recesses defined within isolator 215 to allow seating of an o-ring or elastomeric element, which may facilitate coupling with the flow adapter 220. The various components of the flow assembly 200 can be formed of a metal (such as aluminum or stainless steel), a ceramic, graphite, silicon carbide (SiC), quartz (such as transparent quartz or opaque quartz), and/or other materials. The isolation 215 can be formed of a thermally conductive material to provide a thermal break, isolator 215 may be formed of a less thermally conductive material.

Flow adapter 220 may be coupled with the second end 212 of the isolator 215. Flow adapter 220 can include a first end face 217 and a second end face 218 opposite the first end. Flow adapter 220 may define one or more central cavities through portions of flow adapter 220. For example, from first end face 217, an inlet cavity 219, or a first central channel, may extend at least partially through flow adapter 220 towards second end face 218, and may extend through any length of flow adapter 220. The inlet cavity 219 may extend less than half of a length through flow adapter 220, may extend about half of the length of flow adapter 220, or may extend more than half of the length of flow adapter 220. The inlet cavity 219 (e.g., central channel) may include a diameter of a shape circumscribing the smaller flow openings 214 of isolator 215, such as by having a radius substantially similar to or equivalent to a radius defined from a central axis through isolator 215 and extending to an outer edge of a diameter of the flow openings 214. For example, inlet cavity 219 may have a circular or ovular shape that includes one or more diameters that may extend tangentially with an outer portion of the flow openings 214 of isolator 215.

Flow adapter 220 may define a base of inlet cavity 219 within the flow adapter 220, which may define a transition from inlet cavity 219 to a plurality of flow openings 225 that may at least partially extend through flow adapter 220. The transition may occur at a midpoint through the adapter, which may be at any position along a length of the adapter. For example, second flow openings 225 may extend from a base of inlet cavity 219 towards the second end face 218 of the flow adapter 220, and may extend fully through the second end face 218. In one or more embodiments, the second flow openings 225 may extend through a mid-portion of flow adapter 220 from a first end accessing the inlet cavity 219 to a second end accessing an outlet cavity 221, which may extend into the second end face 218 of the flow adapter 220. The outlet cavity 221 (which can be a second central channel) may have a diameter similar to the inlet cavity 219, or may have a diameter greater than or less than the diameter of the inlet cavity 219. The second flow openings 225 may have a diameter less than or about 50% of a diameter of the inlet cavity 219, and may have a diameter less than or about 40%, less than or about 30%, less than or about 20%, less than or about 10%, less than or about 5%, or less of the diameter of the inlet cavity 219.

Flow adapter 220 may include one or more angled flow openings 222 (such as one or more ports) formed in an outer surface of the flow adapter 220, such as formed in a sidewall or side portion of the flow adapter 220. The one or more angled flow openings 222 can respectively flow a gas (such as a precursor) to be mixed with a precursor flowed from the plasma source 210. The gas(es) flowed through the one or more angled flow openings 222 can flow to an inner flow opening 223 prior to flowing to the outlet cavity 221. In an embodiment where different gases are supplied through different angled flow openings 222, the gases are mixed in the inner flow opening 223. In the outlet cavity 221 the gas(es) flowing from the inner flow opening 223 (e.g., central flow opening) are mixed with the plasma gas(es) supplied from the plasma source 210 and flowing through the second flow openings 225. The inner flow opening 223 can extend along a central longitudinal axis of the flow adapter 220.

The present disclosure contemplates that the inner opening 223 can extend to the inlet cavity 219 (as shown in ghost with numeral 226b) such that mixing of gases can occur in the inlet cavity 219 (and then flow through the second flow openings 225), in addition to or in place of the mixing in the outlet cavity 221. The present disclosure contemplates that the flow adapter 220 may include any version of the inner opening 223 extending towards the first end face 217 and/or the second end face 218 of flow adapter 220.

Flow adapter 220 may be made of a similar or different material from isolator 215. In one or more embodiments, the flow adapter 220 is formed of a metal (such as aluminum or stainless steel, an oxide thereof, or a treated surface thereof), a ceramic, graphite, silicon carbide (SiC), quartz (such as transparent quartz or opaque quartz), and/or other materials. Interior surfaces of flow adapter 220 may be coated with one or more materials to protect flow adapter 220 from damage that may be caused by the gases flowing therein. For example, the coating may include anodizing, yttrium oxide, and/or barium titanate. The flow adapter 220 may include trenches 227 and 228, which may be annular trenches, and may be configured to seat o-rings or other sealing elements.

The second end face 218 of the flow adapter 220 may optionally include a recess extending into the flow adapter 220, and within which a first baffle plate 231 may be seated. The first baffle plate 231 may optionally be included in some system configurations, and may provide improved mixing of a first precursor and second precursor flowing through flow adapter 220. The first baffle plate 231 may include one or more apertures or channels through which the precursors may flow, which may increase uniformity of mixing of the precursors.

A plate assembly 229 includes a spacer plate 230 that can be coupled to the flow adapter 220. The spacer 230 may be or include ceramic, and may be formed of a similar material as isolator 215 and/or flow adapter 220. Spacer plate 230 may include a central opening 232 therethrough. The central opening 232 (e.g., an aperture) can include a taper. A portion of central opening 232 adjacent the outlet cavity 221 may have a diameter equal to or similar to a diameter of the outlet cavity 221. The plate assembly 229 includes a manifold 235 that may be coupled to the spacer plate 230 at a first end 236 or first surface, and may be coupled with the processing chamber 100 (such as a plate of the lid assembly of the processing chamber 100) at a second end 237 opposite first end 236. The manifold 235 includes a flow opening 238 (such as a central channel), which may extend from first end 236 to second end 237 and may be configured to deliver precursors into the processing chamber 100. The manifold 235 can also flow one or more second gases that can be different in composition than the one or more gas(es) supplied through the one or more angled flow openings 222. The manifold 235 may provide a second mixing stage. For example, in the manifold 235 the one or more second gases can be mixed with the gas(es) supplied through the one or more angled flow openings 222 and the plasma gas(es) supplied from the plasma source 210. The one or more second gases flow through one or more side flow openings 239 (e.g., ports) formed in a sidewall of the manifold 235. The manifold 235 may include one or more trenches formed in the first end 236. For example, mixing manifold 235 may define a first trench 240, and a second trench 241, which may provide fluid access from the one or more side flow openings 239 to a central opening 238. For example, the one or more side flow openings 239 may provide fluid connection to one or both trenches 240, 241.

In one or more embodiments, the one or more second gases supplied through a sidewall of the manifold 235 include an inert gas (such as argon), one or more etching precursors (such as one or more hydrogen-containing precursors, one or more fluorine-containing precursors, and/or one or more halogen-containing precursors), one or more selectivity precursors, one or more dopant precursors, and/or one or more other precursor(s). In one or more embodiments, the one or more gases supplied through a sidewall of the flow adapter 220 include an inert gas (such as argon), one or more etching precursors (such as one or more hydrogen-containing precursors, one or more fluorine-containing precursors, and/or one or more halogen-containing precursors), one or more selectivity precursors, one or more dopant precursors, and/or one or more other precursor(s), and the plasma gas supplied from the plasma source 210 include plasma effluents (such as radicals, for example hydrogen radicals). In one or more embodiments, the one or more second gases supplied through a sidewall of the manifold 235 have a different composition than the one or more gases supplied through a sidewall of the flow adapter 220.

By mixing gases (such as precursors, for example etchants) prior to delivery to the processing chamber 100, the flow assembly 200 may provide an etchant having uniform properties prior to being distributed about a chamber and substrate. Additionally, by providing multiple stages of mixing, more uniformity of mixing may be provided for the precursors, which can facilitate uniform and adjustable processing. As an example, processes performed with the present application may have more uniform results across a substrate surface. The illustrated stack of components of the flow assembly 200 may limit particle accumulation by reducing the number of elastomeric seals included in the stack, which may degrade over time and produce particles that may affect processes being performed.

Similar to the first baffle plate 231 described previously, the flow assembly 200 may optionally include a second baffle plate 249, which when included, may be included with or instead of first baffle plate 231. For example, the second baffle plate 249 may be seated in a recess formed in the manifold 235. The second baffle plate 249 may include one or more openings (such as apertures or channels) through which the precursors may flow, which may increase uniformity of mixing of the precursors.

In the implementation shown in FIG. 2, the processing chamber 100 may include a number of components in a stacked arrangement. The processing chamber 100 may include a gasbox 250, a blocker plate 260, a faceplate 270, an optional ion suppression element 280, and a lid spacer 290. The components may be utilized to distribute a precursor or set of precursors through the chamber to provide a uniform delivery of etchants or other precursors to a substrate for processing. The gasbox 250, the blocker plate 260, the faceplate 270, the optional ion suppression element 280, and the lid spacer 290 may be part of a lid assembly of the processing chamber 100. A heater 248 may be configured to heat the processing chamber 100. The heater 248 may be a plate heater or resistive element heater. The blocker plate 260 may includes a plurality of openings 263 (such as apertures) therethrough.

The plate assembly 229 can be coupled to the processing chamber 100. The plasma source 210 and the isolator 215 are part of a plasma source assembly 201. The flow adapter 220 is coupled between the plasma source assembly 201 and the plate assembly 229. The plasma source assembly 201 is operable to supply a plasma gas to the processing volume 126, the flow adapter 220 is operable to supply one or more first gases to the processing volume 126, and the plate assembly 229 (such as the manifold 235) is operable to supple one or more second gases to the processing volume 126.

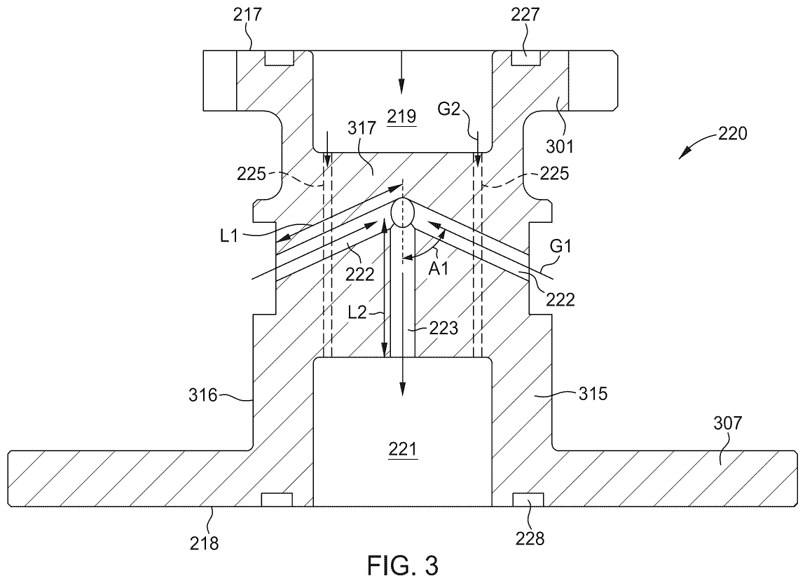

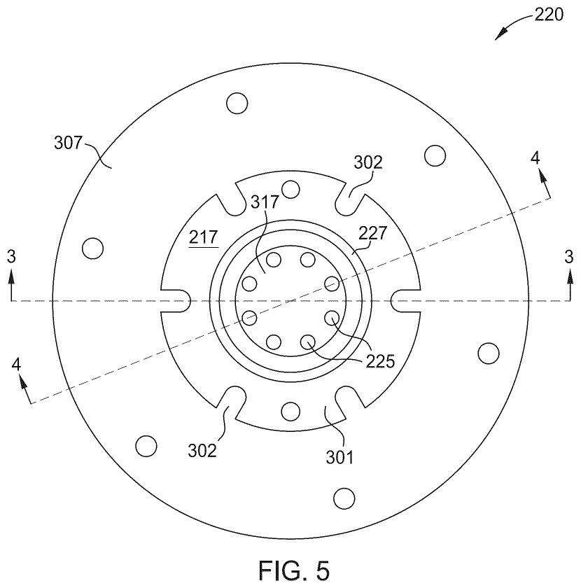

FIG. 3 is an enlarged side cross sectional view of the flow adapter 220 shown in FIG. 2, along Section 3-3 shown in FIG. 5, according to one or more embodiments.

The flow adapter 220 includes a first flange 301 configure to couple to the isolator 215 of the plasma source assembly 201, and a second flange 307 configured to coupled to the spacer plate 230 of the plate assembly 229. The flow adapter 220 includes a conduit 315 extending at least partially between the first flange 301 and the second flange 307. The conduit 315 includes an outer face 316 and the inner flow opening 223. The flow adapter 220 includes the one or more angled flow openings 222 (a plurality is shown) extending between the outer face 316 and the inner flow opening 223. The one or more angled flow openings 222 extend from the outer face 316 and to the inner flow opening 223. The one or more angled flow openings 222 are oriented at an oblique angle A1 relative to the inner flow opening 223. In one or more embodiments, the inner flow opening 223 extends between the outlet cavity 221 and an inward end of the respective one or more angled flow openings 222. The second flange 307 has a larger outer diameter than the first flange 301. The inlet cavity 219 is formed in the first end face 217 of the first flange 301 and the outlet cavity 221 is formed in the second end face 218 of the second flange 307.

A baffle 317 of the conduit 315 is disposed between the inlet cavity 219 and the outlet cavity 221. The second flow openings 225 (e.g., a plurality of holes) extend through the baffle 317 to fluidly connect the inlet cavity 219 to the outlet cavity 221. The plurality of second flow openings 225 are fluidly separated from the one or more angled flow openings 222 by a material (such as a metallic material) of the baffle 317, such that a gas G1 flowing through the angled flow openings 222 is fluidly separate from a gas G2 (such as a plasma gas, for example radicals) flowing through the second flow openings 225, prior to the gas G1 and the gas G2 mixing in the outlet cavity 221. In such an embodiment, the gas G2 can flow to interact with the plasma generated using the plasma source 210, and the gas G1 bypasses the plasma generated using the plasma source 210. The baffle 317 is bounded on both sides by the cavities 219, 221, which can be recessed formed in the respective end faces 217, 218.

The oblique angle A1 can be measured between a longitudinal axis of the inner flow opening 223 and a longitudinal axis of the respective angled flow opening 222. The oblique angle A1 is greater than 0 degrees and less than 80 degrees. In one or more embodiments, the oblique angle A1 is greater than 0 degrees and is equal to or lesser than 60 degrees. In one or more embodiments, the oblique angle A1 is within a range of 55 degrees to 70 degrees, such as 60 degrees to 70 degrees, for example 64 degrees to 66 degrees. In one or more embodiments, the oblique angle A1 is within a range of 10 degrees to 40 degrees, such as 20 degrees to 30 degrees, for example 24 degrees to 26 degrees.

The one or more angled flow openings 222 have a first diameter that is a ratio of a second diameter of the outlet cavity. The ratio is at least 0.5. In one or more embodiments, the ratio is within a range of 0.7 to 0.8, such as 0.74 to 0.76. The one or more angled flow openings 222 have a first length L1 and the inner flow openings 223 has a second length L2. In one or more embodiments, the second length L2 is a ratio of the first length L1, and the ratio is at least 1.0, such as at least 1.25. In one or more embodiments, the ratio of the second length L2 relative to the first length L1 is at least 1.5, such as at least 2.0.

The present disclosure contemplates that the parts (such as the first flange 301, the second flange 307, the conduit 315, and the baffle 317) of the flow adapter 220 can be separate bodies, or can be integrally formed as a single body. For example, the first flange 301, the second flange 307, the conduit 315, and the baffle 317 can be sections of a single body that is integrally formed.

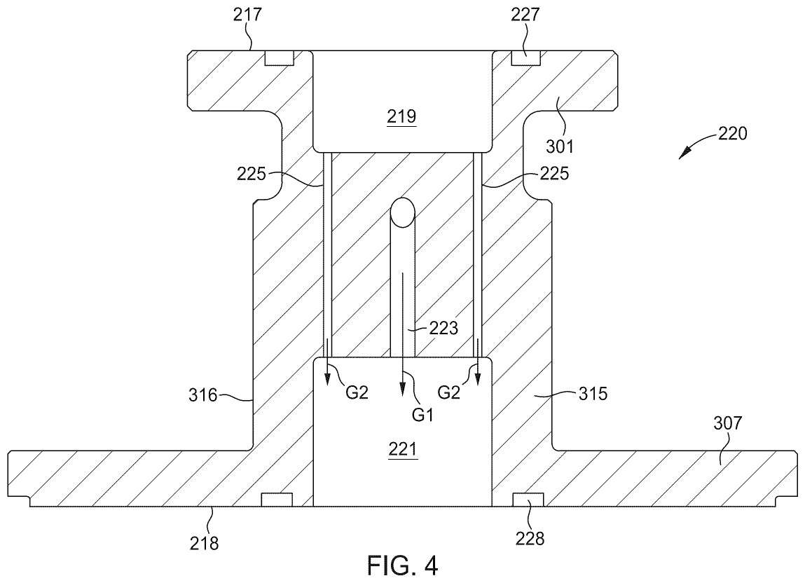

FIG. 4 is a side cross sectional view of the flow adapter 220 shown in FIG. 2, along Section 4-4 shown in FIG. 5, according to one or more embodiments.

FIG. 5 is a schematic top view of the flow adapter 220 shown in FIG. 2, according to one or more embodiments.

The first flange 301 includes a plurality of notches 302 formed in an outer edge of the first flange 301.

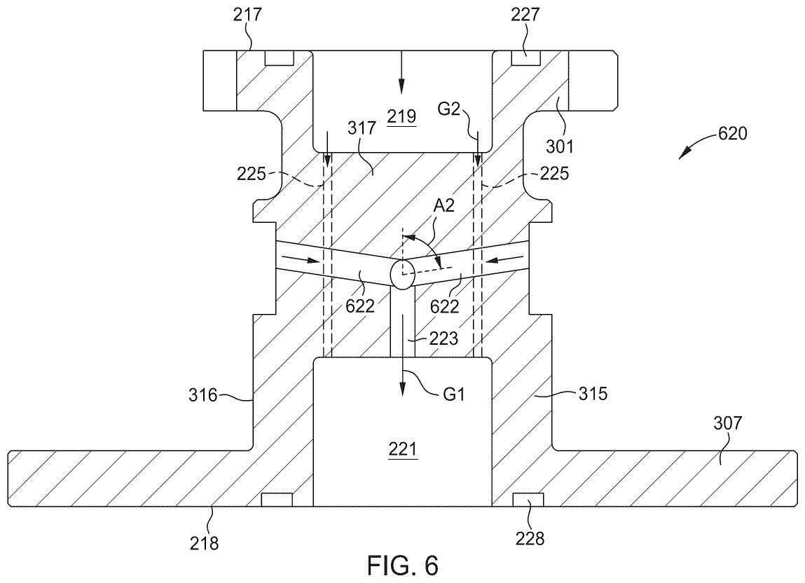

FIG. 6 is an enlarged side cross sectional view of a flow adapter 620, according to one or more embodiments.

The flow adapter 620 is similar to the flow adapter 220 shown in FIGS. 2-5 and includes one or more aspects, features, components, operations and/or properties thereof. The flow adapter 620 includes one or more angled flow openings 622 that are similar to the one or more angled flow openings 222 but angle toward the second flange 307 in a radially inward direction. The one or more angled flow openings 222 in FIG. 2 angle toward the first flange 301 in a radially inward direction. Referring to FIG. 6, the one or more angled flow openings 622 are oriented at an oblique angle A2.

The oblique angle A2 is greater than 0 degrees and less than 80 degrees. In one or more embodiments, the oblique angle A2 is greater than 0 degrees and is equal to or lesser than 60 degrees. In one or more embodiments, the oblique angle A2 is within a range of 65 degrees to 79 degrees degrees, such as 74 degrees to 76 degrees. In one or more embodiments, the oblique angle A2 is within a range of 10 degrees to 40 degrees, such as 20 degrees to 30 degrees, for example 24 degrees to 26 degrees.

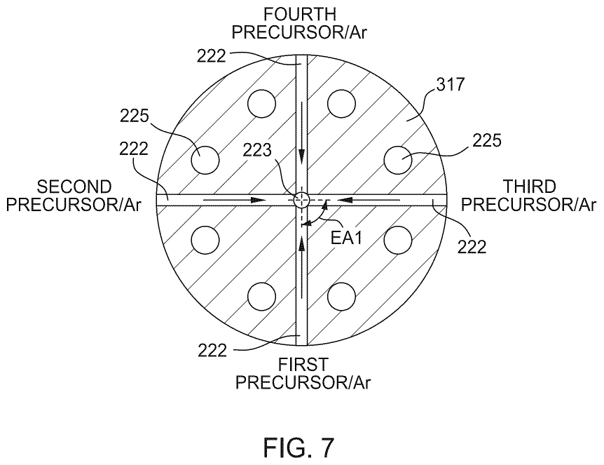

FIG. 7 is a schematic top cross sectional view of the baffle 317 shown in FIG. 3, according to one or more embodiments.

The one or more angled flow openings 222 include a plurality of angled flow openings 222 azimuthally spaced from each other by an equidistant angle EA1. In one or more embodiments, a value of the equidistant angle EA1 multiple by the number of angled flow openings 222 equals 360 degrees. The respective angled flow openings 222 can flow different gas compositions to the inner flow opening 223. For example, one angled flow opening 222 can flow a first precursor and argon, one angled flow opening 222 can flow a second precursor and argon, one angled flow opening 222 can flow a third precursor and argon, and one angled flow opening 222 can flow argon and a fourth precursor. In one or more embodiments, the argon flow through the respective angled flow openings 222 can be adjusted to adjust etching for a more uniform etching substrate map.

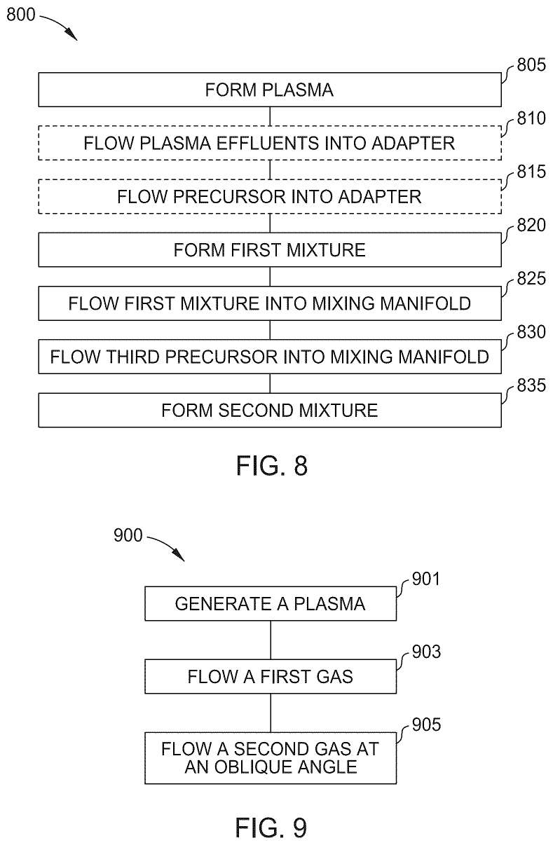

FIG. 8 is a schematic block diagram view of a method 800 of substrate processing, according to one or more embodiments. The method 800 may be conducted in the processing system 101.

Operation 805 includes generating a plasma. As an example, a remote plasma may be generated using a precursor, such as a fluorine-containing precursor. The precursor may be delivered to a remote plasma unit to be dissociated to produce plasma effluents. In one or more embodiments, etchant precursors may be omitted from the remote plasma unit (such as the plasma source assembly 201), which may protect the unit from damage, and allow adjusting of the plasma power to provide specific dissociation of the precursor as may be beneficial to particular processes being conducted.

At optional operation 810, plasma gas (such as plasma effluents, for example radicals or ions) may be flowed into an adapter (such as the flow adapter 220) coupled to the remote plasma unit (such as the plasma source assembly 201).

At optional operation 815, a hydrogen-containing precursor may be flowed into the adapter. The adapter may be configured to provide mixing of the plasma gas and the hydrogen-containing precursor within the adapter, to produce a first mixture at operation 820, which may be further mixed through a baffle plate as previously described.

At operation 825, the first mixture may be flowed from the adapter into a mixing manifold (e.g., the manifold 235).

At operation 830, a third precursor may be flowed into the mixing manifold (e.g., the manifold 235). The third precursor may include an additional hydrogen-containing precursor, an additional halogen-containing precursor, or other combinations of precursors. The mixing manifold may be configured to perform a second stage of mixing of the third precursor with the first mixture, which may produce a second mixture at operation 835.

FIG. 9 is a schematic block diagram view of a method 900 of substrate processing, according to one or more embodiments. The method 900 may be conducted in the processing system 101.

Operation 901 includes generating a plasma.

Operation 903 includes flowing a first gas through the baffle 317 of the conduit 315 and into the processing volume 126.

Operation 905 includes flowing a second gas through the baffle 317 of the conduit 315 and into the processing volume 126. The flowing of the second gas flows at an oblique angle (such as the oblique angle A1 or the oblique angle A2) relative to the first gas.

Benefits of the present disclosure includes enhanced flow stabilization and reduced turbulence of flow (such as turbulence of etchant gases), longer injection paths, more uniform flow of gases for uniform processing (such as uniformity of etching), added adjustability knob of argon flow for processing uniformity, and reduced mechanical complexity and enhanced modularity in structural footprints. As an example, the flow adapters 220, 620 may allow improved precursor mixing externally to the chamber, while protecting components from etchant damage. While components of a chamber may be exposed to etchants that may cause wear over time, the present disclosure may limit these components to those that may be more easily replaced and serviced. For example, the present technology may limit exposure of internal components of a remote plasma unit, which may allow protection to be applied to the remote plasma unit. Benefits also include enhanced processing selectivity (such as etching selectivity) and enhanced control of interfacial contamination.

It is contemplated that one or more aspects disclosed herein may be combined. As an example, one or more aspects, features, components, operations and/or properties of the processing chamber 100, the processing system 101, the lid assembly 104, the flow assembly 200, the plasma source assembly 201, the plate assembly 229, the flow adapter 220, the flow adapter 620, the oblique angle A1, the oblique angle A2, the method 800, and/or the method 900 may be combined. Moreover, it is contemplated that one or more aspects disclosed herein may include some or all of the aforementioned benefits. As an example, one or more operations of the method 800 can be used in addition to or in place of one or more operations of the method 900.

While the foregoing is directed to embodiments of the present disclosure, other and further embodiments of the disclosure may be devised without departing from the basic scope thereof, and the scope thereof is determined by the claims that follow.

What is claimed is:

1. A flow adapter for mounting to a processing chamber, comprising:
a first flange;
a second flange; and
a conduit extending at least partially between the first flange and the second flange, the conduit comprising:
an outer face,
an inner flow opening, and
one or more angled flow openings extending between the outer face and the inner flow opening, the one or more angled flow openings oriented at an oblique angle relative to the inner flow opening.

2. The flow adapter of claim 1, further comprising an outlet cavity, wherein the inner flow opening extends between the outlet cavity and an inward end of the respective one or more angled flow openings.

3. The flow adapter of claim 2, wherein the one or more angled flow openings have a first diameter that is a ratio of a second diameter of the outlet cavity, and the ratio is at least 0.5.

4. The flow adapter of claim 3, wherein the ratio is within a range of 0.7 to 0.8.

5. The flow adapter of claim 2, wherein the second flange has a larger outer diameter than the first flange, and the outlet cavity is formed in an end face of the second flange.

6. The flow adapter of claim 5, further comprising an inlet cavity formed in an end face of the first flange, wherein a baffle of the conduit is disposed between the inlet cavity and the outlet cavity.

7. The flow adapter of claim 6, further comprising a plurality of holes extending through the baffle to fluidly connect the inlet cavity to the outlet cavity, wherein the plurality of holes are fluidly separated from the one or more angled flow openings by a metallic material of the baffle.

8. The flow adapter of claim 1, wherein the oblique angle is greater than 0 degrees and less than 80 degrees.

9. The flow adapter of claim 8, wherein the oblique angle is greater than 0 degrees and equal to or lesser than 60 degrees.

10. The flow adapter of claim 1, wherein the one or more angled flow openings include a plurality of angled flow openings azimuthally spaced from each other by an equidistant angle.

11. A processing system comprising:
a processing chamber comprising a processing volume;
a plate assembly operable to supply a gas to the processing volume,
a plasma source assembly operable to supply a plasma gas to the processing volume,
a flow adapter coupled between the plate assembly and the plasma source assembly, the flow adapter comprising:
a first flange coupled to the plasma source assembly,
a second flange coupled to the plate assembly,
an inner flow opening, and
one or more angled flow openings extending to the inner flow opening, the one or more angled flow openings oriented at an oblique angle relative to the inner flow opening.

12. The processing system of claim 11, wherein the flow adapter further comprises an outlet cavity, and the inner flow opening extends between the outlet cavity and an inward end of the respective one or more angled flow openings.

13. The processing system of claim 12, wherein the one or more angled flow openings have a first diameter that is a ratio of a second diameter of the outlet cavity, and the ratio is at least 0.5.

14. The processing system of claim 13, wherein the ratio is within a range of 0.7 to 0.8.

15. The processing system of claim 12, further comprising an inlet cavity, wherein a baffle of the flow adapter is disposed between the inlet cavity and the outlet cavity.

16. The processing system of claim 11, wherein the oblique angle is greater than 0 degrees and less than 80 degrees.

17. The processing system of claim 16, wherein the oblique angle is greater than 0 degrees and equal to or lesser than 60 degrees.

18. A method of substrate processing, comprising:
generating a plasma;
flowing a first gas through a baffle of a conduit and into a processing volume; and
flowing a second gas through the baffle of the conduit and into the processing volume, the flowing of the second gas flows at an oblique angle relative to the first gas.

19. The method of claim 18, wherein the second gas is fluidly separated from the first gas in the baffle, and the second gas mixes with the first gas in an outlet cavity of the conduit.

20. The method of claim 18, wherein the first gas flows to interact with the plasma, and the second gas bypasses the plasma.
